(19) United States
(12) Patent Application Publication
(10) Pub. No.: US 2008/0193863 A1
(43) Pub. Date: Aug. 14, 2008

(54) MASK SET FOR MICROARRAY, METHOD OF FABRICATING MASK SET, AND METHOD OF FABRICATING MICROARRAY USING MASK SET

(76) Inventors: Jae-pil Shin, Suwon-si (KR); Jin-sook Choi, Suwon-si (KR); Jung-hwan Hah, Hwaseong-si (KR); Moon-hyun Yoo, Suwon-si (KR); Jong-bae Lee, Seongnam-si (KR)

Correspondence Address: F. CHAU & ASSOCIATES, LLC, 130 WOODBURY ROAD, WOODBURY, NY, 11797, US

(21) Appl. No.: 12/030,647

(22) Filed: Feb. 13, 2008

(30) Foreign Application Priority Data
Feb. 13, 2007 (KR) 10-2007-0014934

(51) Int. Cl. G03F 7/00; G03F 1/00

(52) U.S. Cl. 430/5; 430/322

(57) ABSTRACT

Provided are a mask set for in-situ synthesizing probes of a microarray, a method of fabricating the mask set, and a method of fabricating the microarray using the mask set. A mask set for a microarray includes a plurality of masks for in-situ synthesizing probes onto a substrate which includes an array of a plurality of probe cells, wherein each mask includes light-transmitting regions and light-blocking regions, each probe cell corresponds to a light-transmitting region or a light-blocking region, and a pattern of each light-transmitting region is corrected for an optical proximity effect.

This application claims priority from Korean Patent Application No. 10-2007-0014934 filed on Feb. 13, 2007 in the Korean Intellectual Property Office, the contents of which are herein incorporated by reference in their entirety.

### BACKGROUND OF THE INVENTION

1. Technical Field

The present disclosure is directed to a mask set, and more particularly, to a mask set for in-situ synthesizing probes of a microarray, a method of fabricating the mask set, and a method of fabricating the microarray using the mask set.

2. Description of the Related Art

Advances in the genome project have revealed genome nucleotide sequences of various organisms. Accordingly, there is a growing interest in microarrays. Microarrays are widely used for gene expression profiling, genotyping, detection of mutations and polymorphisms, such as single nucleotide polymorphisms (SNPs), analysis of proteins and peptides, screening of potential medicine, development and production of new medicine, and the like.

A microarray includes a plurality of probes fixed to a substrate. The probes may be directly fixed to the substrate by spotting or in-situ synthesized using photolithography and then fixed to the substrate. In particular, in-situ synthesis using photolithography is recently drawing attention because it facilitates mass production.

A plurality of masks are used for the in-situ synthesis of probes. Each mask includes light-transmitting regions and light-blocking regions. In addition, the light-transmitting regions of each mask respectively correspond to probe cells that are to be synthesized with monomers. Generally, each probe cell is substantially square or rectangular, and a light-transmitting region corresponding to each probe cell is also substantially square or rectangular.

However, when the pattern of a light-transmitting region is square, it is either not exposed or insufficiently exposed at edges or sides thereof due to an optical proximity effect, which, in turn, partially hinders the in-situ synthesis of probes on the periphery of a corresponding probe cell. If a design rule of the probe cell is reduced to increase the integration density of a microarray, a proportion of an area, where the in-situ synthesis is hindered in the probe cell, is increased. As a result, an insufficient number of probes are synthesized in a probe cell of a limited size, thereby reducing the reliability of the microarray as a medium of analysis.

### SUMMARY OF THE INVENTION

Embodiments of the present invention provide a mask set for a microarray, the mask set including light-transmitting regions which can be accurately exposed as far as the periphery of corresponding probe cells.

Embodiments of the present invention also provide a method of fabricating a mask set for a microarray, the mask set including light-transmitting regions which can be accurately exposed as far as the periphery of corresponding probe cells.

Embodiments of the present invention also provide a method of fabricating a microarray using the mask set.

However, the objectives of the present invention are not restricted to the one set forth herein. The above and other features of the present invention will become more apparent to one of daily skill in the art to which the present invention pertains by referencing a detailed description of the present invention given below.

According to an aspect of the present invention, there is provided a mask set for a microarray. The mask set includes a plurality of masks for in-situ synthesizing probes onto a substrate which includes an array of a plurality of probe cells, wherein each mask includes light-transmitting regions and light-blocking regions, each probe cell corresponds to a light-transmitting region or a light-blocking region, and a pattern of each light-transmitting region is corrected for an optical proximity effect.

According to another aspect of the present invention, there is provided a method of fabricating a mask set for a microarray. The method includes providing a plurality of mask layouts for in-situ synthesizing probes onto a substrate which includes an array of a plurality of probe cells, correcting a pattern of each light-transmitting region in each mask layout for an optical proximity effect; and fabricating a plurality of masks using the mask layouts which are corrected for the optical proximity effect, wherein each mask layout includes light-transmitting regions and light-blocking regions and each probe cell corresponds to a light-transmitting region or a light-blocking region.

According to another aspect of the present invention, there is provided a method of fabricating a microarray. The method includes providing a substrate including an array of a plurality of probe cells and having a surface protected by a photolabile protecting group; and in-situ synthesizing probes of the microarray using a mask set for a microarray, the mask set including a plurality of masks, wherein each mask includes light-transmitting regions and light-blocking regions, each probe cell corresponds to a light-transmitting region or a light-blocking region, and a pattern of each light-transmitting region is corrected for an optical proximity effect.

### BRIEF DESCRIPTION OF THE DRAWINGS

The above and other features of embodiments of the present invention will become more apparent by describing in detail exemplary embodiments thereof with reference to the attached drawings.

FIG. 1 is a perspective view of a microarray fabricated according to an embodiment of the present invention.

FIG. 2 is a cross-sectional view of the microarray taken along a line II-II′ of FIG. 1.

FIG. 3 is a plan view of a mask according to an embodiment of the present invention.

FIG. 4 is a cross-sectional view of the mask taken along a line IV-IV′ of FIG. 3.

FIGS. 5A through 5C are cross-sectional views for explaining a method of fabricating the mask illustrated in FIG. 4.

FIG. 6 is a schematic perspective view of a mask set according to an embodiment of the present invention.

FIG. 7 is an arrangement plan of light-transmitting and light-blocking regions of a mask according to an embodiment of the present invention.

FIG. 8 is a plan view of a pattern of a light-transmitting region Tc1 at coordinates (1, 1) illustrated in FIG. 7 according to an embodiment of the present invention.

FIG. 9 is an arrangement plan of light-transmitting and light-blocking regions of a mask according to another embodiment of the present invention.

FIG. 10A is a plan view of a pattern of a light-transmitting region Tc2 at coordinates (1, 1) illustrated in FIG. 9 according to an embodiment of the present invention.

FIGS. 10B and 10C are plan views illustrating modified embodiments of FIG. 10A.

FIG. 11 is a flowchart illustrating a method of fabricating a mask according to an embodiment of the present invention.

FIG. 12 is an arrangement plan for explaining a method of determining a pattern of a light-transmitting region of a mask according to an embodiment of the present invention, wherein the arrangement plan includes light-transmitting and light-blocking regions arranged randomly.

FIGS. 13A through 13D are plan views for illustrating a method of determining a pattern of a light-transmitting region Tc3 at coordinates (1, 1) illustrated in FIG. 12 according to an embodiment of the present invention.

### DETAILED DESCRIPTION OF EXEMPLARY EMBODIMENTS

Embodiments of the present invention will now be described more fully with reference to the accompanying drawings, in which exemplary embodiments of the invention are shown. The invention may, however, be embodied in many different forms and should not be construed as being limited to the embodiments set forth herein. Like reference numerals in the drawings denote like elements, and thus their description will be omitted.

Hereinafter, embodiments of the present invention will be described in detail with reference to the accompanying drawings.

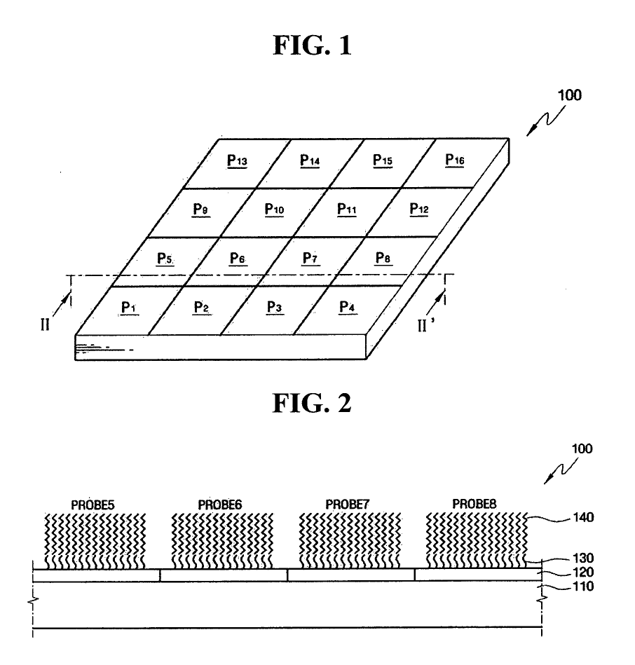

FIG. 1 is a perspective view of a microarray 100 fabricated according to an embodiment of the present invention. FIG. 2 is a cross-sectional view of the microarray 100 taken along a line II-II′ of FIG. 1.

Referring to FIGS. 1 and 2, the microarray 100 includes a substrate 110 and a plurality of probes 140. The probes 140 are coupled onto the substrate 110. The microarray 100 may further include a fixing layer 120 and/or a linker 130 between the probes 140 and the substrate 110. The fixing layer 120 and/or the linker 130 couples the probes 140 to the substrate 110.

The substrate 110 may be, for example, a flexible or rigid substrate. An example of a flexible substrate includes a membrane or plastic film such as nylon and nitrocellulose. Examples of a rigid substrate include a silicon substrate and a transparent glass substrate formed of soda lime glass. In the case of the silicon substrate or the transparent glass substrate, non-specific binding rarely occurs during hybridization. In addition, various thin-film fabrication processes and a photolithography process, which are already established and applied to the process of fabricating semiconductor devices or liquid crystal display (LCD) panels, can also be applied to fabricate the silicon substrate or the transparent glass substrate.

The probes 140 may be, for example, oligomer probes. An oligomer is a polymer composed of two or more covalently bonded monomers, and its molecular weight may be approximately 1,000 or less. The oligomer may include approximately 2 through 500 monomers. More specifically, the oligomer may include approximately 5 through 30 monomers. However, the oligomer, which is mentioned in the present invention, is not limited to the above figures, and it encompasses everything that can be called ‘oligomer’ in the art.

Each monomer of an oligomer probe may be, for example, a nucleoside, a nucleotide, an amino acid, or a peptide.

Each of the nucleosides and nucleotides may include a methylated purine or pyrimidine and an acylated purine or pyrimidine as well as well-known purine and pyrimidine bases. Examples of the purine and pyrimidine bases may include adenine (A), guanine (G), thymine (T), cytosine (C), and uracil (U). In addition, each of the nucleosides and nucleotides may include ribose and deoxyribose sugar, but also modified sugar obtained by replacing one or more hydroxyl groups with halogen atoms or aliphatic families or by being bonded to functional groups such as ether and amine.

The amino acid may be an L-, D-, or a nonchiral amino acid found in nature, a modified amino acid, or an amino acid analog.

The peptide is a compound created by an amino bond between a carboxyl group of an amino acid and an amino group of another amino acid.

Therefore, each of the oligomer probes 140 may be formed of two or more nucleocides, nucleotides, amino acids, or peptides.

Each of the probes 140 may be formed by in-situ synthesis of probe monomers. The in-situ synthesis of the probe monomers may be performed using a mask set which includes a plurality of masks. The masks and the mask set will be described in detail later.

The fixing layer 120 interposed between the substrate 110 and the probes 140 couples the probes 140 to the substrate 110. The fixing layer 120 may be formed of a substantially stable material under a hybridization analysis condition, that is, a material which is not hydrolyzed when contacting phosphate of pH6-9 or a TRIS buffer. For example, the fixing layer 120 may be formed of a silicon oxide film such as a plasma-enhanced tetraethyl orthosilicate (PE-TEOS) film, a high density plasma (HDP) oxide film, a P—SiH₄ oxide film, or a thermal oxide film, a silicate such as a hafnium silicate or a zirconium silicate, a metal oxynitride film such as a silicon oxynitride film, a hafnium oxynitride (HfON) film or a zirconium oxynitride film, a metal oxide film such as a titanium oxide film, a tantalum oxide film, an aluminum oxide film, a hafnium oxide film, a zirconium oxide film or an indium tin oxide (ITO), a metal such as polyimide, polyamine, gold, silver, copper or palladium, or a polymer such as polystyrene, a polyacrylic acid or polyvinyl.

The linker 130 may optionally be interposed between the fixing layer 120 and the probes 140. The linker 130 couples the probes 140 to the fixing layer 120. Therefore, the linker 130 may be formed of a material including a functional group which can be coupled to the fixing layer 120 and a functional group which can be coupled to the probes 140. Furthermore, the linker 130 may provide a spatial margin for hybridization. To this end, the length of the linker 130 may be, but is not limited to, about 6 through 50 atoms.

The microarray 100 configured as described above includes a plurality of probe cells. For illustrative purposes, an exemplary, non-limiting microarray includes first through sixteenth probe cells P₁-P₁₆. It is to be understood that microarrays according to other embodiments can be configured with a different number of probe cells. Each of the first through sixteenth probe cells P₁-P₁₆ is a segment to which the probes 140 are coupled. Therefore, the first through sixteenth probe cells P₁-P₁₆ include the probes 140 and an object to which the probes 140 are coupled. As described above, the object to which the probes 140 are coupled may be the substrate 110, the fixing layer 120, and/or the linker 130. Therefore, it can be understood that anything referred to as a probe cell includes the object and at least one of the substrate 110, the fixing layer 120, and the linker 130.

The first through sixteenth probe cells P₁-P₁₆ can be distinguished from one another by the sequence of the probes 140 coupled to the fixing layer 120 and/or by physical patterns of the fixing layer 120.

More specifically, probes included in the same probe cell have substantially the same probe sequence. On the other hand, probes included in different probe cells have different probe sequences. Referring to FIG. 2, all probes PROBE 5 included in the fifth probe cell P₅ have the same probe sequence. The same applies to probes PROBE 6, PROBE 7, and PROBE 8. However, when it comes to the relationship between the probes PROBE 6, PROBE 7 and PROBE 8, the probes PROBE 6, PROBE 7 and PROBE 8 have different probe sequences since they are included in different probe cells, i.e., the sixth through eighth probe cells P₆ -P₈, respectively. That is, the fifth probe cell P₅ including the probes PROBE 5, the sixth probe cell P₆ including the probes PROBE 6, the seventh probe cell P₇ including the probes PROBE 7, and the eighth probe cell P₈ including the probes PROBE 8 sequentially arranged from the left in FIG. 2 may be distinguished from one another by their probe sequences. Similarly, the same applies to the first through fourth probe cells P₁-P₄ and the ninth through sixteenth probe cells P₉-P₁₆.

Another standard for distinguishing the first through sixteenth probe cells P₁-P₁₆ is a physical pattern. That is, the first through sixteenth probe cells P₁-P₁₆ may be physically patterned, and an isolation region (not shown) may be interposed between them.

As illustrated in FIG. 1, the first through sixteenth probe cells P₁-P₁₆ may be patterns arranged in rows and columns and have substantially the same size and shape.

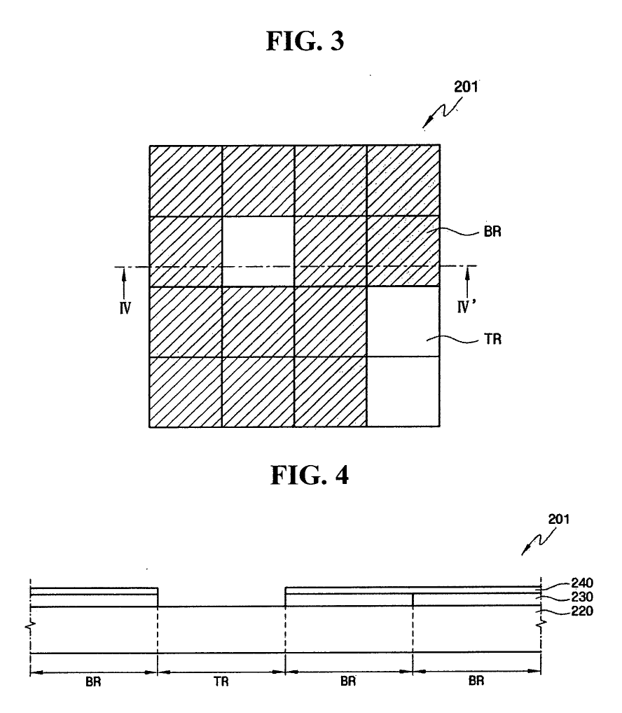

Hereinafter, a mask used for the in-situ synthesis of the probes 140 in the microarray 100 will be described. FIG. 3 is a plan view of a mask 201 according to an embodiment of the present invention. FIG. 4 is a cross-sectional view of the mask 210 taken along a line IV-IV′ of FIG. 3.

Referring to FIG. 3, the mask 201 may be divided into a plurality of segments respectively corresponding to probe cells in a microarray. Each segment is occupied by any one of a light-transmitting region TR and a light-blocking region BR. The total number of light-transmitting regions TR and light-blocking regions BR in the mask 201 is equal to the number of corresponding probe cells regardless of whether the above regions are adjacent to one another. Therefore, in FIG. 3, there are three light-transmitting regions TR and thirteen light-blocking regions BR.

While each light-transmitting region TR of the mask 201 corresponds to a probe cell of the microarray, its pattern does not perfectly match that of each probe cell. The pattern of each light-transmitting region TR illustrated in FIG. 3 is a mere example and does not represent an actual pattern. In addition, predetermined correction patterns are added to the pattern of each light-transmitting region TR of the mask 201, which will be described in detail later.

A cross-sectional structure of the mask 201 will now be described with reference to FIG. 4. The mask 201 includes a base 220 formed of transparent glass, a light-blocking pattern layer 230 partially formed on the base 220 and formed of an opaque material such as chrome, and a reflection preventive pattern layer 240, for example, formed of chrome oxide.

The light-transmitting and light-blocking regions TR and BR of the mask 201 are determined according to whether the light-blocking pattern layer 230 is formed. That is, a region where the light-blocking region 230 is formed are determined to be the light-blocking region BR, and a region where the light-blocking region 230 is not formed is determined to be the light-transmitting regions TR since the transparent base 220 is exposed.

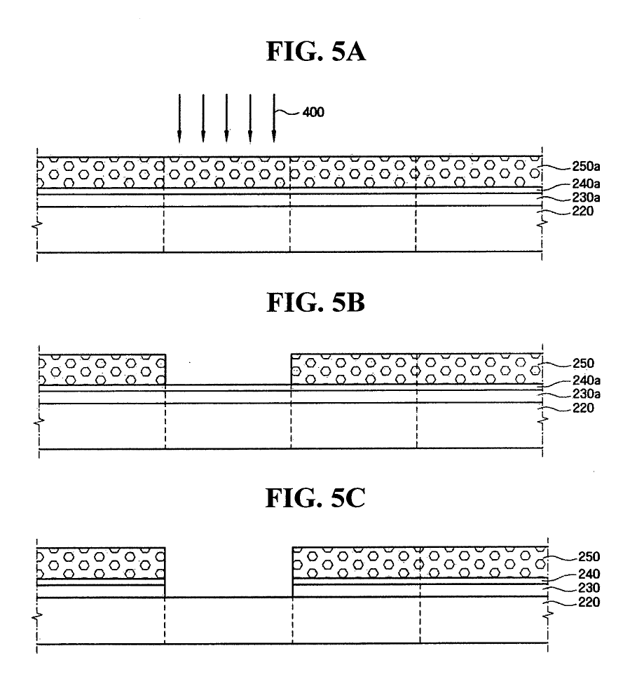

A method of fabricating the mask 201 will now be described with reference to FIGS. 5A through 5C. FIGS. 5A through 5C are cross-sectional views for explaining the method of fabricating the mask 201 illustrated in FIG. 4.

Referring to FIG. 5A, a stack is provided of a light-blocking layer 230a, a reflection preventive layer 240a, and a photoresist film 250a sequentially formed on the base 220. The photoresist film 250a is selectively exposed as indicated by reference numeral 400. Here, a region (hereinafter, referred to as an exposure region) of the photoresist film 250a, which is to be exposed, may be selected based on a mask layout which is prepared in advance. In addition, the mask layout may include correction patterns, which will be described later.

Referring to FIG. 5B, the selected exposure region of the photoresist film 250a is removed in a develop process. Consequently, a photoresist pattern 250 exposing the reflection preventive layer 240a is formed.

Referring to FIG. 5C, the exposed reflection preventive layer 240a and the light-blocking layer 230a beneath the exposed reflection preventive layer 240a are etched. Consequently, the reflection preventive pattern layer 240 and the light-blocking pattern layer 230 are formed, and the substrate 220 thereunder is exposed. The exposed reflection preventive layer 240a and the light-blocking layer 230a may be anisotropically etched.

Next, if the photoresist pattern 250 is removed, the mask 201 illustrated in FIG. 4 can be completed. The region where the reflection preventive layer 240a and the light-blocking layer 230a therebeneath are removed is the light-transmitting region TR.

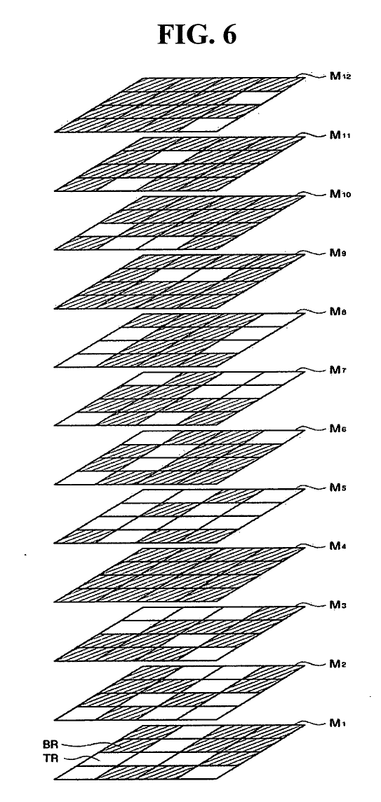

FIG. 6 is a schematic perspective view of a mask set according to an embodiment of the present invention. The mask set includes a plurality of masks fabricated according to the above-mentioned embodiments of the present invention. Referring to FIG. 6, an exemplary, non-limiting mask set according to an embodiment of the invention includes 12 masks M₁-M₁₂. Each of the masks M₁-M₁₂ is used for at least one lithography process to synthesize probes of a microarray. Therefore, the mask set illustrated in FIG. 6 may be used for a total of at least 12 lithography processes to synthesize probes of a microarray. It is to be understood, however, that this mask set is illustrative, and mask sets according to other embodiments of the invention can have a different number of masks.

Each lithography process is performed to synthesize a probe monomer. Therefore, each of the masks M₁-M₁₂ can be allocated to any one of a plurality of probe monomers that are to be synthesized. For example, if a monomer that is to be synthesized is a nucleotide phosphoamidite monomer having any one of adenine (A), guanine (G), thymine (T), and cytosine (C) as a base, the monomer is allocated to each of the masks M₁-M₁₂.

As mentioned above in the embodiment of FIG. 3, while each light-transmitting region TR of each of the masks M₁-M₁₂ corresponds to each probe cell, its pattern does not perfectly match that of each probe cell.

More specifically, the pattern of each probe cell has a substantially rectangular shape, such as a square shape. However, the rectangular shape is vulnerable to an optical proximity effect. That is, exposure reduction and/or pattern distortion may occur at edges or sides of a rectangle due to the optical proximity effect. Therefore, if the pattern of each light-transmitting region in each mask is substantially rectangular-shaped to correspond to the shape of each probe cell, the entire area of each probe cell may not have a uniform exposure effect due to the optimal proximity effect.

Generally, edges or sides of the pattern of a probe cell are either not exposed or insufficiently exposed, which, in turn, partially hinders the in-situ synthesis of probes on the periphery of the probe cell. If a design rule of the probe cell is reduced to increase the integration density of the microarray, a proportion of an area, where the in-situ synthesis is hindered in the probe cell, is increased. As a result, an insufficient number of probes are synthesized in the probe cell of a limited size, thereby reducing the reliability of the microarray as a medium of analysis.

Hence, each light-transmitting region of a mask according to an embodiment of the present invention includes additional correction patterns in consideration of the optical proximity effect. The light-transmitting region added with the correction patterns will now be described in more detail.

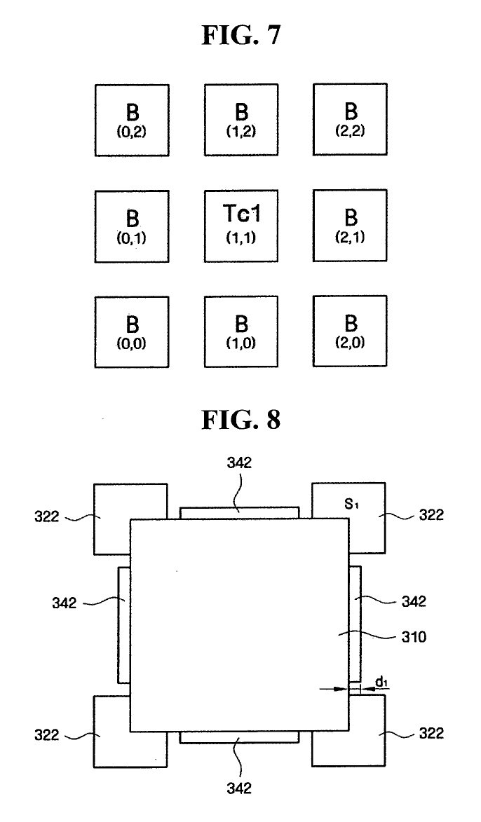

FIG. 7 is an arrangement plan of light-transmitting and light-blocking regions of a mask according to an embodiment of the present invention. FIG. 8 is a plan view of a pattern of a light-transmitting region Tc1 at coordinates (1, 1) illustrated in FIG. 7 according to an embodiment of the present invention.

Referring to FIG. 7, the light-transmitting region Tc1, which is to be determined, is surrounded by a total of eight regions. That is, a region at coordinates (2, 1) to the right of the light-transmitting region Tc1 and a region at coordinates (0, 1) to the left of the light-transmitting region Tc1 are adjacent to the light-transmitting region Tc1 with right and left sides of the light-transmitting region Tc1 therebetween, respectively. A region at coordinates (1, 2) above the light-transmitting region Tc1 and a region at coordinates (1, 0) under the light-transmitting region Tc1 are adjacent to the light-transmitting region Tc1 with upper and lower sides of the light-transmitting region Tc1 therebetween, respectively. In addition, a region at coordinates (2, 2) to the upper right of the light-transmitting region Tc1, a region at coordinates (0, 2) to the upper left of the light-transmitting region Tc1, a region at coordinates (2, 0) to the lower right of the light-transmitting region Tc1, and a region at coordinates (0, 0) to the lower left of the light-transmitting region Tc1 are adjacent to the light-transmitting region Tc1 with corners of the light-transmitting region Tc1 therebetween, respectively. In FIG. 7, all regions indicated by character ‘B’ and excluding the light-transmitting region Tc1 are light-blocking regions.

In FIG. 7, since the light-transmitting region Tc1 is surrounded by the light-blocking regions in all directions, the optical proximity effect caused by an adjacent light-transmitting region does not occur. However, the light-transmitting region Tc1 itself has optical proximity effect correction patterns due to its structure.

FIG. 8 illustrates an example in which optical proximity effect correction patterns are added to the light-transmitting region Tc1 positioned as illustrated in FIG. 7. Referring to FIG. 8, the pattern of the light-transmitting region Tc1 includes a substantially rectangular main pattern 310 substantially corresponding to a probe cell and additional correction patterns. In the rectangular light-transmitting pattern, since the exposures of each corner and side of the rectangular pattern are interfered with and offset, the correction patterns are added to each corner and side of the main pattern 310. In the present embodiment, the correction patterns include first serif correction patterns 322 and first bias margin correction patterns 342.

The first serif correction patterns 322 are added respectively to corners of the main pattern 310 which are not adjacent to other light-transmitting regions in a corner direction of the main pattern 310. In the present embodiment, the first serif correction patterns 322 are added respectively to four corners of the main pattern 310. Each of the first serif correction patterns 322 added respectively to the corners of the main pattern 310 is a substantially square pattern with an area of S₁.

The first bias margin correction patterns 342 are added respectively to sides of the main pattern 310 which are not adjacent to other light-transmitting regions in a side direction of the main pattern 310. In the present embodiment, the first bias margin correction patterns 342 are added respectively to four sides of the main pattern 310. Each of the first bias margin correction patterns 342 respectively added to the sides of the main pattern 310 is a substantially rectangular pattern with a first margin width of d₁.

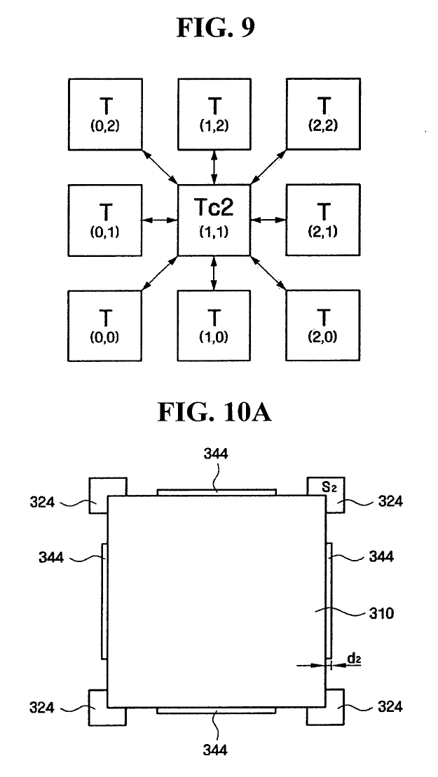

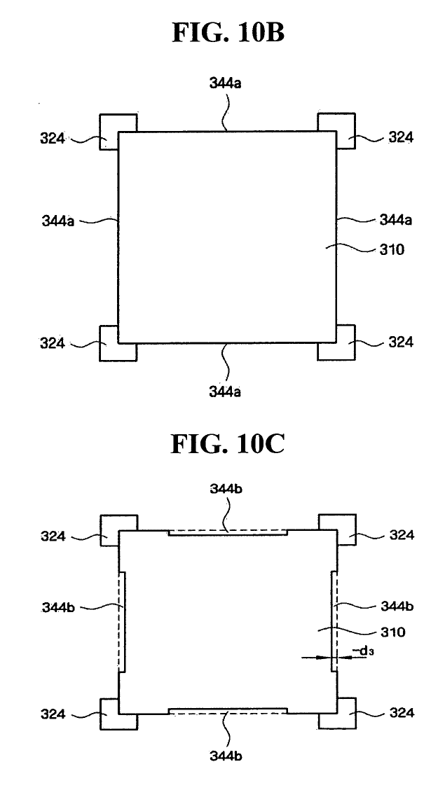

FIG. 9 is an arrangement plan of light-transmitting and light-blocking regions of a mask according to another embodiment of the present invention. FIG. 10A is a plan view of a pattern of a light-transmitting region Tc2 at coordinates (1, 1) illustrated in FIG. 9 according to an embodiment of the present invention. FIGS. 10B and 10C are plan views illustrating modified embodiments of FIG. 10A. In FIG. 9, character ‘T’ indicates a light-transmitting region.

Referring to FIG. 9, the light-transmitting region Tc2, which is to be determined, is surrounded by a total of eight light-transmitting regions like the light-transmitting region Tc1 illustrated in FIG. 7. However, the light-transmitting region Tc2 according to the present embodiment is different from the light-transmitting region Tc1 in that it is surrounded by other adjacent light-transmitting regions. That is, since the light-transmitting region Tc2 is surrounded by the adjacent light-transmitting regions in all directions, the optical proximity effect may occur. Therefore, the effect of the adjacent light-transmitting regions on the light-transmitting region Tc2 cannot be ignored. In this regard, the optical proximity effect is corrected in consideration of the effect of these adjacent light-transmitting regions.

FIG. 10A illustrates an example in which optical proximity effect correction patterns are added to the light-transmitting region Tc2 positioned as illustrated in FIG. 9. Referring to FIG. 10A, the pattern of the light-transmitting region Tc2 according to the present embodiment is substantially identical to the pattern of the light-transmitting region Tc1 according to the embodiment of FIG. 8 in that the exposures of each corner and side of the rectangular pattern are interfered with and offset and thus correction patterns are added to each corner and side of a main pattern 310. However, since the exposure interference and offsetting effect on the rectangular pattern is reduced as compared with those on the pattern illustrated in FIG. 8 due to the adjacent light-transmitting regions, the correction patterns added to the rectangular pattern illustrated in FIG. 10A are different from those added to the pattern illustrated in FIG. 8. That is, in the present embodiment, the correction patterns include second serif correction patterns 324 and second bias margin correction patterns 344.

The second serif correction patterns 324 are added respectively to corners of the main pattern 310 which are adjacent to other light-transmitting regions in a corner direction of the main pattern 310. In the present embodiment, the second serif correction patterns 324 are added respectively to four corners of the main pattern 310. Each of the second serif correction patterns 324 added respectively to the corners of the main pattern 310 is a substantially square pattern with an area of S₂. Here, the first serif correction patterns 322 are larger than the second serif correction patterns 324.

In addition, the second bias margin correction patterns 344 are added to sides of the main pattern 310 which are adjacent to other light-transmitting regions in a side direction of the main pattern 310. In the present embodiment, the second bias margin correction patterns 344 are added to four sides of the main pattern 310. Each of the second bias margin correction patterns 344 respectively added to the sides of the main pattern 310 is a substantially rectangular pattern with a first margin width of d₂. Here, the second margin d₂ is smaller than the first margin d, of each of the first bias margin correction patterns 342 described above.

A value of a second margin may vary according to an exposure energy used for the in-situ synthesis of probes. For example, as illustrated in FIG. 10B, a value of a second margin width of each of the second bias margin correction patterns 344a may be zero. In addition, as illustrated in FIG. 10C, a value of a second margin width −d₃ of each of the second bias margin correction patterns 344b may be a negative value. Despite these various examples, a universally applicable principle is that the first margin width magnitude of each of the first bias margin correction patterns 342 is greater than the second margin width magnitude of each of the second bias margin correction patterns 344, 344a and 344b. That is, the difference between values of the first and second margin magnitudes is a positive value.

Hereinafter, a method of determining a pattern of a light-transmitting region using rules for adding correction patterns to the pattern of the light-transmitting region when light-transmitting and light-blocking regions are randomly arranged will be described. The correction patterns are added to the pattern of the light-transmitting region when a mask layout is determined in a mask fabrication process.

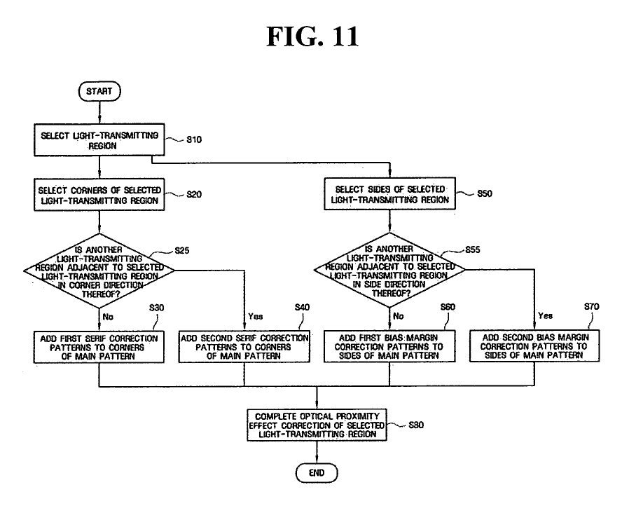

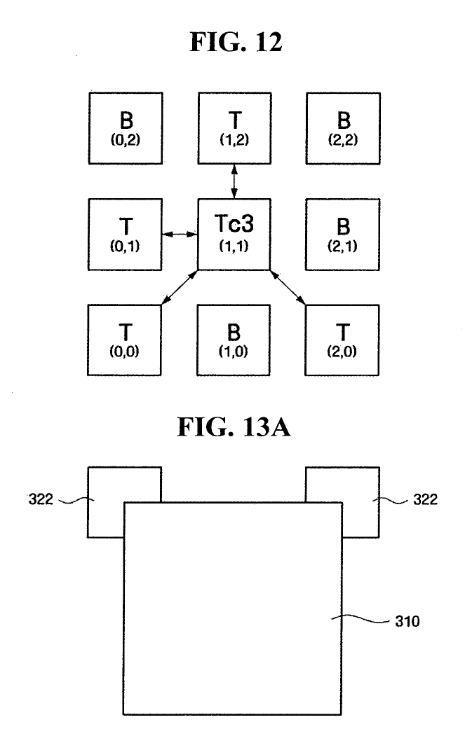

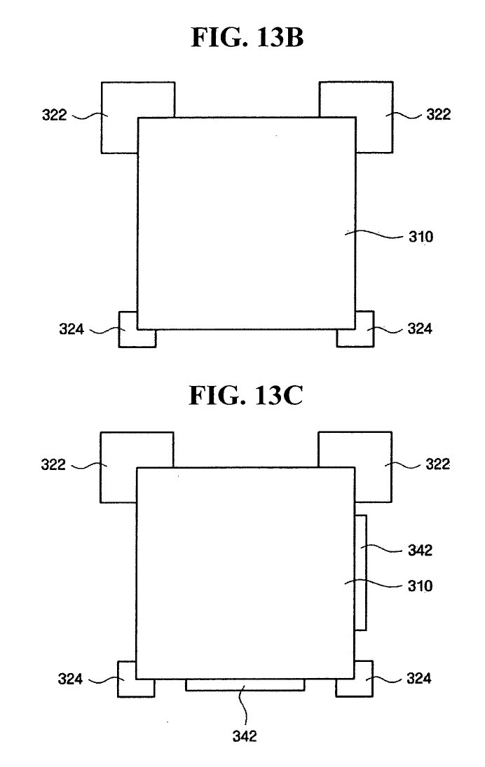

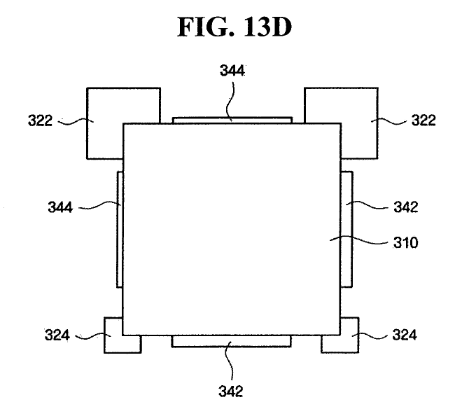

FIG. 11 is a flowchart illustrating a method of fabricating a mask according to an embodiment of the present invention. FIG. 12 is an arrangement plan for explaining a method of determining a pattern of a light-transmitting region of a mask according to an embodiment of the present invention, wherein the arrangement plan includes light-transmitting and light-blocking regions arranged randomly. FIGS. 13A through 13D are plan views for illustrating a method of determining a pattern of a light-transmitting region Tc3 at coordinates (1, 1) illustrated in FIG. 12 according to an embodiment of the present invention.

Referring to FIG. 11, a segment (hereinafter, referred to as a ‘light-transmitting region’) occupied by a light-transmitting region is selected from segments of a mask layout which respectively correspond to probe cells of a microarray (operation S10). It is assumed that the selected light-transmitting region is the light-transmitting region Tc3 at the coordinates (1, 1) in the arrangement plan of FIG. 12.

Next, corners of the selected light-transmitting region Tc3 are selected (operation S20).

Then, it is checked whether another light-transmitting region is adjacent to the selected light-transmitting region Tc3 in a corner direction of the selected light-transmitting region Tc3 (operation S25). Referring to FIG. 12, the selected light-transmitting region Tc3 is adjacent to other light-transmitting regions at coordinates (2, 0) and (0, 0) to the lower right and lower left of the selected light-transmitting region Tc3, respectively. However, no light-transmitting region is adjacent to the selected light-transmitting region Tc3 at coordinates (2, 2) and (0, 2) to the upper right and upper left of the selected light-transmitting region Tc3, respectively.

Referring to FIGS. 11 and 13A, first serif correction patterns 322 are added respectively to corners of the selected light-transmitting region Tc3 which are not adjacent to other light-transmitting regions in the corner direction of the selected light-transmitting region Tc3 (operation S30). That is, in FIG. 12, the first serf correction patterns 322 are respectively added to corners of the main pattern 310 in directions of the coordinates (2, 2) and (0, 2), i.e., upper right and upper left corners of the main pattern 310.

Referring to FIGS. 11 and 13B, second serif correction patterns 324 are added respectively to corners of the selected light-transmitting region Tc3 which are adjacent to other light-transmitting regions in the corner direction of the selected light-transmitting region Tc3 (operation S40). That is, in FIG. 12, the second serf correction patterns 324 are respectively added to corners at the coordinates (2, 0) and (0, 0), i.e., corners to the lower right and lower left of the main pattern 310.

Consequently, the first and second serif correction patterns 322 and 324 are completed.

Referring back to FIG. 11, sides of the selected light-transmitting region Tc3 are selected (operation S50).

Next, it is checked whether another light-transmitting region is adjacent to the selected light-transmitting region Tc3 in a side direction of the selected light-transmitting region Tc3 (operation S55). Referring to FIG. 12, the selected light-transmitting region Tc3 is adjacent to other light-transmitting regions at coordinates (1, 2) and (0, 1) above and to the left of the selected light-transmitting region Tc3, respectively. However, no light-transmitting region is adjacent to the selected light-transmitting region Tc3 at coordinates (2, 1) and (1, 0) to the right of and under the selected light-transmitting region Tc3, respectively.

Referring to FIGS. 11 and 13C, first bias margin correction patterns 342 are added respectively to sides of the selected light-transmitting region Tc3 which are not adjacent to other light-transmitting regions in the side direction of the selected light-transmitting region Tc3 (operation S60). That is, in FIG. 12, the first bias margin correction patterns 342 are respectively added to sides of the main pattern 310 in directions of the coordinates (2, 1) and (1, 0), i.e., right and lower sides of the main pattern 310.

Referring to FIGS. 11 and 13D, second bias margin correction patterns 344 are added to sides of the selected light-transmitting region Tc3 which are adjacent to other light-transmitting regions in the side direction of the selected light-transmitting region Tc3 (operation S70). That is, in FIG. 12, the second bias margin correction patterns 344 are respectively added to sides of the main pattern 310 in directions of the coordinates (1, 2) and (0, 1), i.e., upper and left sides of the main pattern 310.

Consequently, optical proximity effect correction patterns, i.e., the first and second bias margin correction patterns 342 and 344, are completed in the selected light-transmitting region Tc3 as illustrated in FIG. 11 (operation S80).

The above operations are applied to all light-transmitting regions of the mask layout. As a result, appropriate correction patterns are added to the mask layout according to the number of light-transmitting regions adjacent to each light-transmitting region and directions in which the light-transmitting regions are adjacent to each light-transmitting region, and the mask layout with the appropriate correction patterns is completed. When a mask is fabricated using the mask layout corrected as described above, the optical proximity effect can be substantially eliminated. To fabricate a mask set, correction patterns are added to each mask layout as described above, and a plurality of masks are fabricated based on a plurality of mask layouts added with correction patterns.

The operation of adding correction patterns to a mask layout described above may be stored as data and processed accordingly. Specifically, probe cells of a microarray have substantially identical patterns and are regularly arranged. Therefore, segments of a mask layout respectively corresponding to the probe cells are all standardized. That is, the number and arrangement of regions surrounding any light-transmitting region are identical. In addition, each segment of the mask layout is occupied by either a light-transmitting region or a light-blocking region. Therefore, if such standardized cases are stored as data in a correction pattern library and a correction pattern designated for each piece of data is also stored in the correction pattern library, correction patterns to be added can be more easily and quickly determined using the correction pattern library.

More specifically, in the correction pattern library, for example, those cases where a selected light-transmitting region is adjacent to and is not adjacent to other light-transmitting regions in the corner direction thereof as well as the coordinates of the light-transmitting regions can be stored as data, and the data can be made to correspond to first serif correction pattern data and second serif correction pattern data. Similarly, those cases where a selected light-transmitting region is adjacent to and is not adjacent to other light-transmitting regions in the side direction of a main pattern of the light-transmitting region as well as the coordinates of the light-transmitting regions are stored as data, and the data can be made to correspond to first and second bias margin correction pattern data.

Thereafter, if the number of light-transmitting regions adjacent to the selected light-transmitting region and the coordinates of the light-transmitting regions are checked and input, corresponding first and second serif correction patterns and corresponding first and second bias margin correction patterns can be acquired and added to the main pattern immediately.

A mask and a mask set according to embodiments of the present invention described above are used for in-situ synthesis of probes of a microarray. It may be assumed that a surface of a substrate is protected by a photolabile protecting group for the in-situ synthesis of the probes of the microarray. The substrate includes an array of a plurality of probe cells. If the probe cells are exposed using a mask according to an embodiment of the present invention, some of the probes cells, which correspond to light-transmitting regions of the mask, are exposed and thus the photolabile protecting group in each of the exposed probe cells is resolved. Since the mask used here has been effectively corrected for the optical proximity effect, the probe cells corresponding to the light-transmitting regions of the mask can be fully exposed as far as the peripheries thereof. Accordingly, the reliability of the in-situ synthesis can be enhanced. Since further details of the method of fabricating a microarray using a mask set according to an embodiment of the present invention are widely known to those of ordinary skill in the art, a detailed description thereof will be omitted.

According to a mask set for a microarray according to an embodiment of the present invention, optical proximity effect correction patterns are added to each light-transmitting region of each mask included in the mask set in consideration of the effects of adjacent light-transmitting regions. Therefore, probe cells can be accurately exposed as far as the periphery thereof during the in-situ synthesis of probes of the microarray. Consequently, the reliability of the in-situ synthesis of the probes can be enhanced.

While the present invention has been particularly shown and described with reference to exemplary embodiments thereof, it will be understood by those of ordinary skill in the art that various changes in form and details may be made therein without departing from the spirit and scope of the present invention as defined by the following claims. The exemplary embodiments should be considered in descriptive sense only and not for purposes of limitation.

What is claimed is:

1. A mask set for a microarray, the mask set comprising:
a plurality of masks for in-situ synthesizing probes onto a substrate which comprises an array of a plurality of probe cells,
wherein each mask comprises light-transmitting regions and light-blocking regions, each probe cell corresponds to a light-transmitting region or a light-blocking region, and a pattern of each light-transmitting region is corrected for an optical proximity effect.

2. The mask set of claim 1, wherein each probe cell is substantially rectangular, and serif correction patterns and bias margin correction patterns are added to a substantially rectangular main pattern included in a pattern of the light-transmitting region corresponding to each probe cell.

3. The mask set of claim 2, wherein the serif correction patterns comprise:
first serif correction patterns added respectively to corners of the main pattern of the light-transmitting region which are not adjacent to other light-transmitting regions in a corner direction of the main pattern; and
second serif correction patterns added respectively to corners of the main pattern of the light-transmitting region which are adjacent to other light-transmitting regions in the corner direction of the main pattern.

4. The mask set of claim 3, wherein the first serif correction patterns are larger than the second serif correction patterns.

5. The mask set of claim 2, wherein the bias margin correction patterns comprise:
first bias margin correction patterns added respectively to sides of the main pattern of the light-transmitting region which are not adjacent to other light-transmitting regions in a side direction of the main pattern; and
second bias margin correction patterns added respectively to sides of the main pattern of the light-transmitting region which are adjacent to other light-transmitting regions in the side direction of the main pattern.

6. The mask set of claim 5, wherein the difference between a margin width magnitude of each first bias margin correction pattern and that of each second bias margin correction pattern is a positive value.

7. A method of fabricating a mask set for a microarray, the method comprising:
providing a plurality of mask layouts for in-situ synthesizing probes onto a substrate which comprises an array of a plurality of probe cells,
correcting a pattern of each light-transmitting region in each mask layout for an optical proximity effect; and
fabricating a plurality of masks using the mask layouts which are corrected for the optical proximity effect,
wherein each mask layout comprises light-transmitting regions and light-blocking regions and each probe cell corresponds to a light-transmitting region or a light-blocking region.

8. The method of claim 7, wherein each probe cell is substantially rectangular, and serif correction patterns and bias margin correction patterns are added to a substantially rectangular main pattern included in the pattern of the light-transmitting region corresponding to each probe cell.

9. The method of claim 8, wherein the adding of the serif correction patterns comprises:
adding first serif correction patterns respectively to corners of the main pattern of the light-transmitting region which are not adjacent to other light-transmitting regions in a corner direction of the main pattern; and
adding second serif correction patterns respectively to corners of the main pattern of the light-transmitting region which are adjacent to other light-transmitting regions in the corner direction of the main pattern.

10. The method of claim 9, wherein the first serif correction patterns are larger than the second serif correction patterns.

11. The method of claim 8, wherein the adding of the bias margin correction patterns comprises:
adding first bias margin correction patterns respectively to sides of the main pattern of the light-transmitting region which are not adjacent to other light-transmitting regions in a side direction of the main pattern; and
adding second bias margin correction patterns respectively to sides of the main pattern of the light-transmitting region which are adjacent to other light-transmitting regions in the side direction of the main pattern.

12. The method of claim 11, wherein the difference between a margin width magnitude of each first bias margin correction pattern and that of each second bias margin correction pattern is a positive value.

13. The method of claim 8, wherein the adding of the serif correction patterns and the bias margin correction patterns comprises:
preparing a correction pattern library in which correction patterns to be added to a selected light-transmitting region according to the number of light-transmitting regions adjacent to the selected light-transmitting region and directions in which the light-transmitting regions are adjacent to the selected light-transmitting region are stored as data; and
inputting the number of light-transmitting regions adjacent to the selected light-transmitting region and coordinates of the light-transmitting regions to the correction pattern library and acquiring the correction patterns stored as data from the correction pattern library.

14. The method of claim 13, wherein the correction pattern library comprises:
first serif correction pattern data corresponding to a case where the light-transmitting regions are not adjacent to the selected light-transmitting region in a corner direction of a main pattern of the selected light-transmitting region;
second serif correction pattern data corresponding to a case where the light-transmitting regions are adjacent to the selected light-transmitting region in the corner direction of the main pattern of the selected light-transmitting region;
first bias margin correction pattern data corresponding to a case where the light-transmitting regions are not adjacent to the selected light-transmitting region in a side direction of the main pattern of the selected light-transmitting region; and
second bias margin correction pattern data corresponding to a case where the light-transmitting regions are adjacent to the selected light-transmitting region in the side direction of the main pattern of the selected light-transmitting region.

15. A method of fabricating a microarray, the method comprising:
providing a substrate comprising an array of a plurality of probe cells and having a surface protected by a photolabile protecting group; and
in-situ synthesizing probes of the microarray using a mask set for a microarray, the mask set comprising a plurality of masks,
wherein each mask comprises light-transmitting regions and light-blocking regions, each probe cell corresponds to a light-transmitting region or a light-blocking region, and a pattern of each light-transmitting region is corrected for an optical proximity effect.

16. The method of claim 15, wherein each probe cell is substantially rectangular, and serif correction patterns and bias margin correction patterns are added to a substantially rectangular main pattern included in the pattern of the light-transmitting region corresponding to each probe cell.

17. The method of claim 16, wherein the serif correction patterns comprise:
first serif correction patterns added respectively to corners of the main pattern of the light-transmitting region which are not adjacent to other light-transmitting regions in a corner direction of the main pattern; and
second serif correction patterns added respectively to corners of the main pattern of the light-transmitting region which are adjacent to other light-transmitting regions in the corner direction of the main pattern.

18. The method of claim 17, wherein the first serif correction patterns are larger than the second serif correction patterns.

19. The method of claim 16, wherein the bias margin correction patterns comprise:
first bias margin correction patterns added respectively to sides of the main pattern of the light-transmitting region which are not adjacent to other light-transmitting regions in a side direction of the main pattern; and
second bias margin correction patterns added respectively to sides of the main pattern of the light-transmitting region which are adjacent to other light-transmitting regions in the side direction of the main pattern.

20. The method of claim 19, wherein the difference between a margin width magnitude of each first bias margin correction pattern and that of each second bias margin correction pattern is a positive value.
